(19) United States
(12) Patent Application Publication
(10) Pub. No.: US 2025/0048621 A1
(43) Pub. Date: Feb. 6, 2025

(54) SEMICONDUCTOR MEMORY DEVICE INCLUDING A VERTICAL CHANNEL TRANSISTOR

(71) Applicant: SAMSUNG ELECTRONICS CO., LTD., SUWON-SI (KR)

(72) Inventors: Sunghwan JANG, Suwon-si (KR); Jinbum KIM, Suwon-si (KR); Hyojin PARK, Suwon-si (KR); Sunguk JANG, Suwon-si (KR)

(21) Appl. No.: 18/641,488

(22) Filed: Apr. 22, 2024

(30) Foreign Application Priority Data
Aug. 3, 2023 (KR) 10-2023-0101793

(51) Int. Cl. H10B 12/00; H01L 29/06; H01L 29/423; H01L 29/775; H01L 29/786

(52) U.S. Cl. CPC H10B 12/488; H01L 29/0673; H01L 29/42356; H01L 29/42392; H01L 29/775; H01L 29/78696; H10B 12/315; H10B 12/482; H10B 12/50

(57) ABSTRACT

A semiconductor memory device includes: a plurality of word lines extending in a first direction; a plurality of channel layers alternately arranged with the word lines, wherein the channel layers extend in a second direction; and a plurality of bit lines located on the word lines and the channel layers, and extending in a third direction. The bit lines are electrically connected to the channel layers. The plurality of word lines include: a plurality of selected word lines to which a positive voltage is applied; and a plurality of non-selected word lines to which a negative voltage is applied. The plurality of channel layers include: a selected channel layer that is turned on; and a non-selected channel layer that is turned off.

### CROSS-REFERENCE TO RELATED APPLICATION

This application claims priority under 35 U.S.C. § 119 to Korean Patent Application No. 10-2023-0101793, filed on Aug. 3, 2023, in the Korean Intellectual Property Office, the disclosure of which are incorporated by reference herein in its entirety.

### TECHNICAL FIELD

Embodiments of the present inventive concept relate to a semiconductor memory device. More particularly, embodiments of the present inventive concept relate to a semiconductor memory device including a vertical channel transistor.

### DISCUSSION OF THE RELATED ART

Generally, each unit device in a semiconductor memory (dynamic random-access memory) device has a 1T1C structure that includes one transistor and one capacitor. As the degree of device integration for a semiconductor memory device has continued to increase, a structure for reducing the area of each unit device in a plan view has been under development. A recess-channel cell array transistor (RCAT) structure was initially applied to a semiconductor memory device, but now a buried-channel cell array transistor (BCAT) is commercially available. A vertical-channel cell array transistor (VCAT) structure capable of further reducing the area of a unit device by vertically arranging transistors has recently been under development.

### SUMMARY

According to embodiments of the present inventive concept, a semiconductor memory device includes: a plurality of word lines extending in a first direction; a plurality of channel layers alternately arranged with the plurality of word lines, wherein the plurality of channel layers extend in a second direction that crosses the first direction; and a plurality of bit lines located on the plurality of word lines and the plurality of channel layers, and extending in a third direction crossing to the first direction and the third direction, and wherein the plurality of bit lines are electrically connected to the plurality of channel layers, wherein the plurality of word lines include: a plurality of selected word lines to which a positive voltage is applied; and a plurality of non-selected word lines to which a negative voltage is applied, and the plurality of channel layers include: a selected channel layer that is turned on; and a non-selected channel layer that is turned off, wherein one pair of word lines adjacent to ends of the selected channel layer are all the selected word lines, and at least one of one pair of word lines adjacent to ends of the non-selected channel layer are each one of the non-selected word lines.

According to embodiments of the present inventive concept, a semiconductor memory device includes: a plurality of channel layers arranged in a first direction and extending in a second direction that is substantially perpendicular to the first direction; a plurality of word lines extending while surrounding at least a portion of outer circumferential surfaces of the plurality of channel layers; a plurality of bit lines located on the plurality of word lines and the plurality of channel layers, and extending in a third direction perpendicular to the first direction and the second direction, wherein the plurality of bit lines are electrically connected to the plurality of channel layers; and a plurality of capacitors electrically connected to the plurality of channel layers, wherein the plurality of word lines include: a plurality of selected word lines to which a positive voltage is applied; and a plurality of non-selected word lines to which a negative voltage is applied, and the plurality of channel layers include: a selected channel layer that is turned on; and a non-selected channel layer that is turned off, wherein the word line surrounding at least a portion of an outer circumferential surface of the selected channel layer is one of the selected word lines, and the word line surrounding at least a portion of an outer circumferential surface of the non-selected channel layer is one of the non-selected word lines.

According to embodiments of the present inventive concept, a semiconductor memory device includes: a plurality of vertical channel transistors; and a plurality of capacitors electrically connected to the plurality of vertical channel transistors, wherein the plurality of vertical channel transistors include: a plurality of word lines extending in a first horizontal direction; a plurality of channel layers alternately arranged with the plurality of word lines, and extending in a vertical direction that is substantially perpendicular to the first horizontal direction; a plurality of gate insulating layers at least partially surrounding the plurality of channel layers; a plurality of bit lines located on the plurality of word lines, the plurality of channel layers, and the plurality of gate insulating layers, and extending in a second horizontal direction that is substantially perpendicular to the first horizontal direction and the vertical direction, wherein the plurality of bit lines are electrically connected to the plurality of channel layers; a plurality of buried contacts (BC) located between the plurality of channel layers and the plurality of capacitors, and electrically connected to the plurality of channel layers; and a plurality of direct contacts (DC) spaced apart from the plurality of buried contacts (BC) with the plurality of channel layers disposed therebetween, and electrically connecting the plurality of channel layers to the plurality of bit lines, wherein the plurality of word lines include: a plurality of selected word lines to which a positive voltage is applied; and a plurality of non-selected word lines to which a negative voltage is applied, and the plurality of channel layers include: a selected channel layer that is turned on; and a non-selected channel layer that is turned off, wherein one pair of word lines adjacent to ends of the selected channel layer in the second horizontal direction are all the selected word lines, and at least one of one pair of word lines adjacent to ends of the non-selected channel layer in the second horizontal direction are each one of the non-selected word lines, wherein the semiconductor memory device further includes a plurality of sources and a plurality of drains located on the plurality of channel layers, wherein a distance between each of at least two of the plurality of word lines and the bit lines in the vertical direction is a first distance or a second distance, and a word line of which a distance in the vertical direction is the first distance and a word line of which a distance in the vertical direction is the second distance are alternately arranged with each other to form a zigzag pattern, wherein the first distance is shorter than the second distance.

### BRIEF DESCRIPTION OF THE DRAWINGS

The above and other aspects of the present inventive concept will become more apparent by describing in detail embodiments thereof, with reference to the accompanying drawings, in which:

FIG. 1 is a perspective view illustrating a semiconductor memory device, according to embodiments of the present inventive concept;

FIG. 2A is a cross-sectional view illustrating a semiconductor memory device in which word lines are arranged in a zigzag pattern, according to embodiments of the present inventive concept;

FIG. 2B is a cross-sectional view illustrating a semiconductor memory device in which word lines are arranged in a zigzag pattern, according to embodiments of the present inventive concept;

FIG. 3A is a cross-sectional view illustrating a semiconductor memory device, according to embodiments of the present inventive concept;

FIG. 3B is a cross-sectional view illustrating a semiconductor memory device, according to embodiments of the present inventive concept;

FIG. 4A is a cross-sectional view illustrating a semiconductor memory device in which word lines are arranged in a gate-all-around shape in a zigzag pattern, according to embodiments of the present inventive concept;

FIG. 4B is a cross-sectional view illustrating a semiconductor memory device in which word lines are arranged in a gate-all-around shape in a zigzag pattern, according to embodiments of the present inventive concept;

FIG. 4C is a cross-sectional view taken along line A-A′ of FIG. 4A;

FIG. 5A is a cross-sectional view illustrating a semiconductor memory device in which word lines and back gates are arranged in a zigzag pattern, according to embodiments of the present inventive concept;

FIG. 5B is a cross-sectional view illustrating a semiconductor memory device in which word lines and back gates are arranged in a zigzag pattern, according to embodiments of the present inventive concept;

FIG. 6A is a cross-sectional view illustrating a semiconductor memory device in which word lines and back gates are arranged in a zigzag pattern, according to embodiments of the present inventive concept;

FIG. 6B is a cross-sectional view illustrating a semiconductor memory device in which word lines and back gates are arranged in a zigzag pattern, according to embodiments of the present inventive concept;

FIG. 7 is a view illustrating an operating method of a semiconductor memory device, according to embodiments of the present inventive concept; and

FIGS. 8, 9, 10, 11, 12, and 13 are views sequentially illustrating a process of a semiconductor memory device, according to embodiments of the present inventive concept.

### DETAILED DESCRIPTION OF THE EMBODIMENTS

Hereinafter, a semiconductor memory device according to embodiments of the present inventive concept will be described in detail with reference to the accompanying drawings. Like reference numerals may denote like elements throughout the specification and drawings, and thus, repetitive descriptions may be omitted. In the accompanying figures, various thicknesses, lengths, and sizes are shown and while the arrangement shown does indeed represent an embodiment of the present inventive concept, it is to be understood that modifications of the various thicknesses, lengths, and sizes may be possible within the spirit and scope of the present inventive concept and the present concept is not necessarily limited to the particular thicknesses, lengths, and sizes shown. In addition, the embodiments of the present inventive concept that are described below are merely examples, and various modifications may be made to the embodiments.

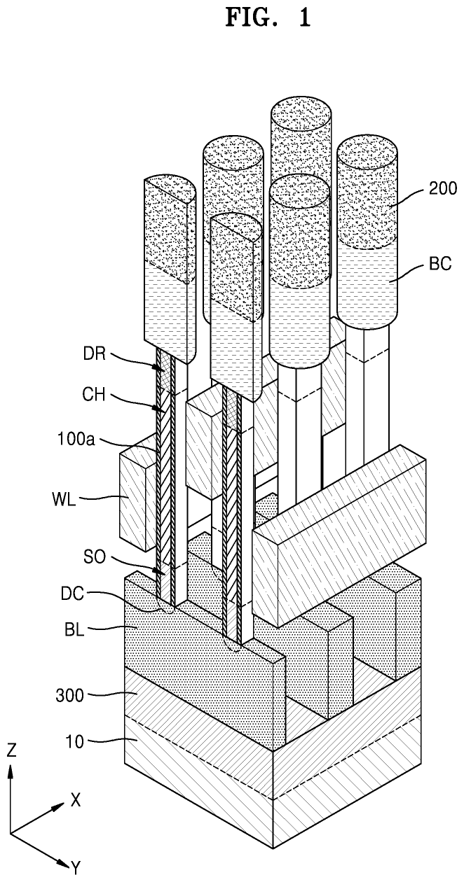

FIG. 1 is a perspective view illustrating a semiconductor memory device, according to embodiments of the present inventive concept.

Referring to FIG. 1, a semiconductor memory device 1 may be a dynamic random-access memory (DRAM) device. The semiconductor memory device 1 includes a plurality of unit devices arranged in an array. Each unit device has a 1T1C structure including one transistor and one capacitor. The semiconductor memory device 1 may include a plurality of word lines WL extending in a first direction X, a plurality of channel layers CH alternately arranged with the plurality of word lines WL in a third direction Y and extending in a second direction Z that is substantially perpendicular to the first direction X, a plurality of bit lines BL extending in the third direction Y that is substantially perpendicular to the first direction X and a second direction Z on the plurality of word lines WL and the plurality of channel layers CH and electrically connected to the plurality of channel layers CH, a plurality of capacitors 200 electrically connected to the plurality of channel layers CH, a plurality of buried contacts BC that are located between the plurality of channel layers CH and the plurality of capacitors 200 and are electrically connected to the plurality of channel layers CH, a plurality of direct contacts DC spaced apart from the plurality of buried contacts BC with the channel layers CH therebetween and electrically connected to the channel layers CH and the bit lines BL, a plurality of gate insulating layers 100a surrounding the plurality of channel layers CH, a peripheral circuit structure 300 including a plurality of peripheral circuits, and a semiconductor substrate 10.

The first direction X and the third direction Y may be horizontal directions that are parallel to a top surface of the semiconductor substrate 10, and the second direction Z may be a vertical direction that is substantially perpendicular to the top surface of the semiconductor substrate 10. However, the present inventive concept is not limited thereto.

The plurality of word lines WL and the plurality of channel layers CH may constitute a vertical channel transistor.

The vertical channel transistor may further include a plurality of sources SO, which are located under the plurality of channel layers CH in the second direction Z, and a plurality of drains DR, which are located above the plurality of channel layers CH in the second direction Z.

The plurality of gate insulating layers 100a may surround at least a portion or the whole of the plurality of channel layers CH.

In the arrangement of the word lines WL in the first direction X, the word lines WL may be disposed at different positions with respect to the second direction Z, and the word lines WL having different positions may be alternately arranged along the third direction Y with the channel layer CH therebetween. For example, the word lines WL may include a first row of word lines WL and a second row of word lines WL that is disposed above the first row of word lines WL with respect to the second direction Z, and the second row of word lines WL may be misaligned with the first row of word lines WL. Positions of the word lines WL that are disposed in the second direction Z are not limited to those illustrated in FIG. 1.

Each of the plurality of bit lines BL may include, for example, polysilicon, metal, conductive metal nitride, conductive metal silicide, conductive metal oxide, or a combination thereof. For example, the bit line BL may include, but is not limited to, doped polysilicon, Al, Cu, Ti, Ta, Ru, W, Mo, Pt, Ni, Co, TiN, TaN, WN, WSi, NbN, TiAl, TIAIN, TiSi, TiSiN, TaSi, TaSIN, RuTiN, NiSi, CoSi, IrOx, RuOx, or a combination thereof. In addition, the bit line BL may include a two-dimensional (2D) semiconductor material. The 2D semiconductor material may include, for example, graphene, carbon nanotubes, or a combination thereof. The bit line BL may have a single or multi-layer structure including the above conductive materials.

The word line WL may include a conductive material. For example, the word line WL may include at least one of a metal, a semiconductor, and an alloy. Examples of the metal may include aluminum (Al), tungsten (W), molybdenum (Mo), titanium (Ti), and tantalum (Ta). Examples of the semiconductor may include a group IV semiconductor material, a group III-V semiconductor material, an oxide semiconductor, a nitride semiconductor, and an oxynitride semiconductor. However, the present inventive concept is not limited thereto. Lengths of the plurality of word lines WL in a vertical direction that is the second direction Z may be the same as each other, or lengths of the plurality of word lines WL in the vertical direction may be different from each other.

The semiconductor substrate 10 may include a semiconductor material. For example, the semiconductor substrate 10 may be a silicon substrate doped with n-type impurities. However, this is merely an example, and the semiconductor substrate 10 may include, for example, a group IV semiconductor material such as germanium (Ge), silicon germanium (SiGe), or silicon carbide (SiC), a group III-V semiconductor material such as gallium arsenide (GaAs), indium arsenide (InAs), or indium phosphide (InP), an oxide semiconductor, a nitride semiconductor, or an oxynitride semiconductor. However, the present inventive concept is not limited thereto. In embodiments of the present inventive concept, the semiconductor substrate 10 may be a silicon-on-insulator (SOI) substrate or a germanium-on-insulator (GOI) substrate. The gate insulating layer 100a may include silicon oxide.

In embodiments of the present inventive concept, the channel layer CH may include a semiconductor material. For example, the channel layer CH may include single crystalline silicon or polysilicon. In embodiments of the present inventive concept, the channel layer CH may include an oxide semiconductor material. The channel layer CH may include at least one of a binary or ternary oxide semiconductor material, which includes a first metal element, a ternary oxide semiconductor material, which includes a first metal element and a second metal element which are different from each other, and a quaternary oxide semiconductor material, which includes a first metal element, a second metal element, and a third metal element which are different from each other. The binary or ternary oxide semiconductor material may be one of, for example, but is not limited to, zinc oxide (ZnxO) (ZnO), gallium oxide (GaxO) (GaO), tin oxide (TixO) (TiO), zinc oxynitride (ZnxOyN) (ZnON), indium zinc oxide (InxZnyO) (IZO), gallium zinc oxide (GaxZnyO) (GZO), tin zinc oxide (SnxZnyO) (TZO), or tin gallium oxide (SnxGayO) (TGO). The quaternary oxide semiconductor material may be any one of, for example, but is not limited to, indium gallium zinc oxide (InxGaYZnzO) (IGZO), indium gallium silicon oxide (InxGaySizO) (IGSO), indium tin zinc oxide (InxSnYZnzO) (ITZO), indium gallium tin oxide (InxGaySnzO) (IGTO), zirconium zinc tin oxide (ZrXZnySnzO) (ZZTO), hafnium indium zinc oxide (HfxInYZnzO) (HIZO), gallium zinc tin oxide (GaXZnySnzO) (GZTO), aluminium zinc tin oxide (AlXZnySnzO) (AZTO), ytterbium gallium zinc oxide (YbxGaYZnzO) (YGZO), or indium aluminum zinc oxide (IAZO).

In embodiments of the present inventive concept, the channel layer CH may be formed of a crystalline oxide semiconductor material or an amorphous oxide semiconductor material. When the channel layer CH is formed of a crystalline oxide semiconductor material, the channel layer CH may have at least one of single crystalline, polycrystalline, spinel, and/or c-axis aligned crystalline (CAAC) structures. In embodiments of the present inventive concept, the channel layer CH may be formed by stacking at least two layers including a first layer, which is formed of a crystalline oxide semiconductor material, and a second layer, which is formed of an amorphous oxide semiconductor material. For example, the channel layer CH may be formed by sequentially stacking a first layer, which is formed of a crystalline oxide semiconductor material, a second layer, which is formed of an amorphous oxide semiconductor material, and a third layer, which is formed of a crystalline oxide semiconductor material.

A plurality of peripheral circuits included in the peripheral circuit structure 300 may drive each unit device included in the semiconductor memory device 1.

The plurality of capacitors 200 that are electrically connected to the plurality of channel layers CH may include a plurality of lower electrodes, an upper electrode, and a capacitor dielectric layer.

The plurality of lower electrodes may be respectively located on the plurality of buried contacts BC.

Each of the plurality of lower electrodes may have a cylindrical shape, that is, a pillar shape whose inside is filled to have a circular horizontal cross-section, but the present inventive concept is not limited thereto. In embodiments of the present inventive concept, each of the plurality of lower electrodes may have a cylindrical shape with a closed lower portion. In embodiments of the present inventive concept, the plurality of lower electrodes may be arranged in a honeycomb shape with a zigzag pattern in a first horizontal direction X or a second horizontal direction Y. In embodiments of the present inventive concept, the plurality of lower electrodes may be arranged in a matrix along the first horizontal direction X and the second horizontal direction Y. The plurality of lower electrodes may be formed of, for example, a metal such as silicon, tungsten, or copper doped with impurities, or a conductive metal compound such as titanium nitride.

The capacitor dielectric layer may conformably cover surfaces of the plurality of lower electrodes. In embodiments of the present inventive concept, the capacitor dielectric layer may be integrally formed to cover top surfaces of the plurality of lower electrodes in a certain area. The capacitor dielectric layer may be formed of, for example, TaO, TaAIO, TaON, AIO, AlSiO, HfO, HfSiO, ZrO, ZrSiO, TiO, TiAIO, BST ((Ba,Sr)TiO), STO(SrTiO), BTO(BaTiO), PZT(Pb,Zr,Ti)O), (Pb,La) (Zr,Ti)O, Ba(Zr,Ti)O, Sr(Zr,Ti)O, or a combination thereof.

The upper electrode may cover the capacitor dielectric layer. The upper electrode may be formed of, for example, W, Ru, RuO, Pt, PtO, Ir, IrO, SrRuO(SRO), (Ba,Sr)RuO(BSRO), CaRuO(CRO), BaRuO, or La(Sr,Co)O. In embodiments of the present inventive concept, the upper electrode may be formed of a metal material. For example, the upper electrode may be formed of W. In embodiments of the present inventive concept, the upper electrode may further include at least one of a doped semiconductor material layer and an interface layer, in addition to the metal material, and may have a stacked structure thereof. The doped semiconductor material layer may include at least one of, for example, doped polysilicon and doped polycrystalline silicon germanium (poly-SiGe). The main electrode layer may be formed of a metal material. The interface layer may include at least one of, for example, metal oxide, metal nitride, metal carbide, and metal silicide.

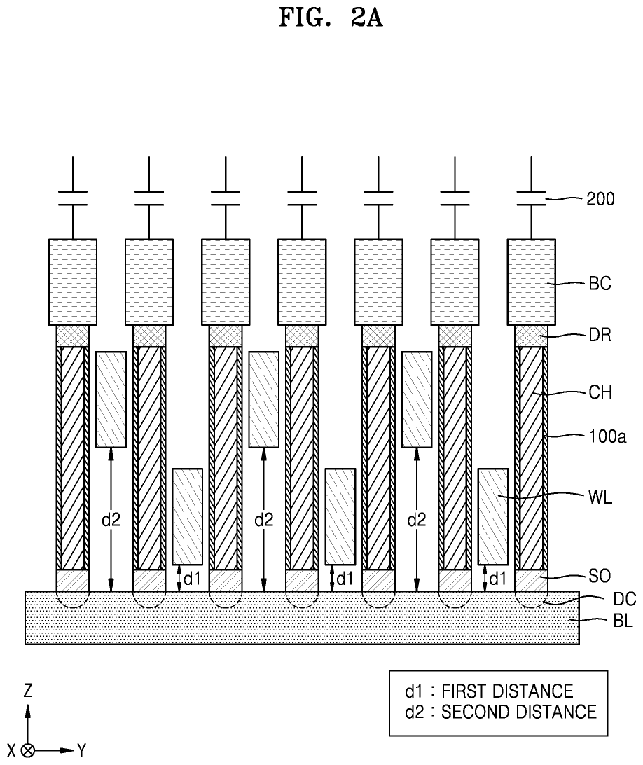

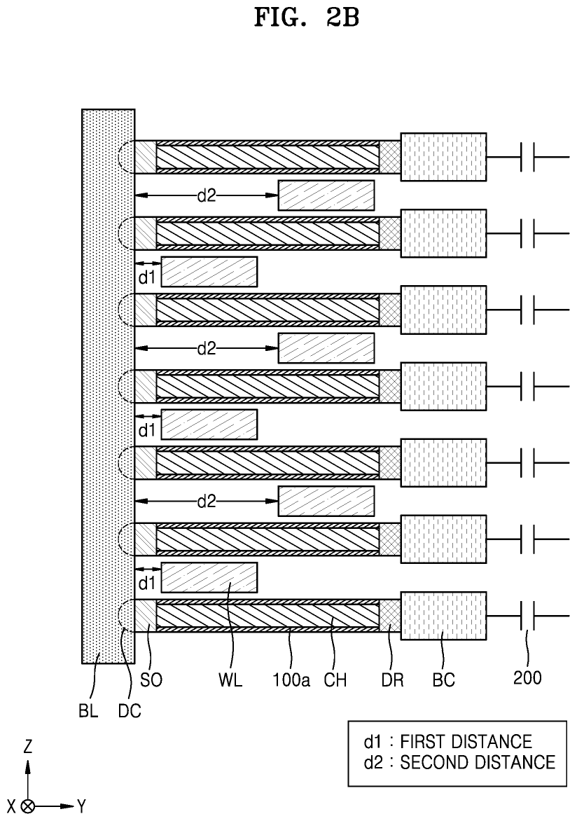

FIG. 2A is a cross-sectional view illustrating a vertical structure semiconductor memory device in which word lines are arranged in a zigzag pattern, according to embodiments of the present inventive concept.

Referring to FIG. 2A, the first direction X and the third direction Y are horizontal directions that are parallel to a top surface of the semiconductor substrate 10 of FIG. 1, and the second direction Z is a vertical direction that is substantially perpendicular to the top surface of the semiconductor substrate 10 of FIG. 1. The semiconductor memory device 1 includes a plurality of bit lines BL, a plurality of word lines WL, a plurality of channel layers CH, and a plurality of capacitors 200.

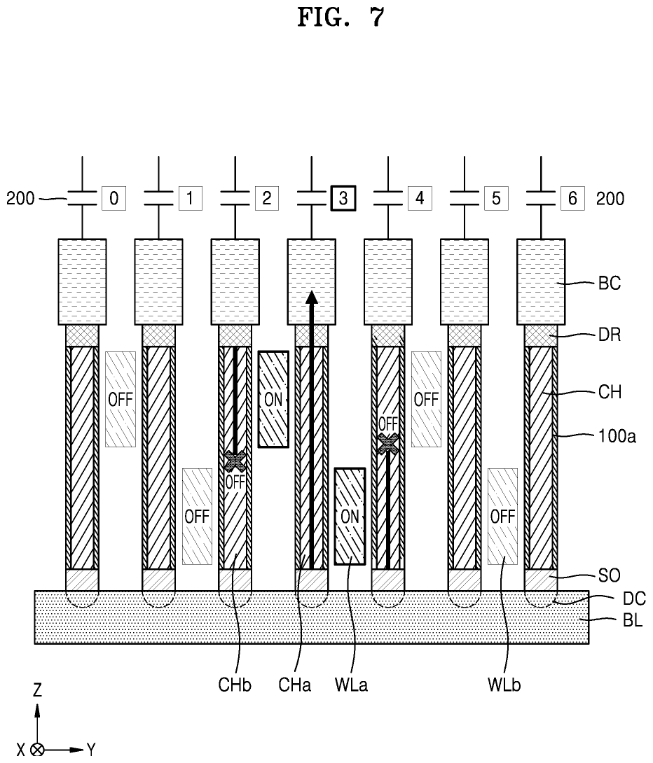

A distance between the word line WL and the bit line BL in the second direction Z may be a first distance d1 or a second distance d2. The first distance d1 and the second distance d2 may be different from each other, and the first distance d1 may be shorter than the second distance d2. In other words, a distance between some of the plurality of word lines WL and the bit line BL in the second direction Z may be the first distance d1, and a distance between some others of the plurality of word lines WL and the bit line BL in the second direction Z may be the second distance d2. The word line WL of which a distance in the second direction Z is the first distance d1 and the word line WL of which a distance in the second direction Z is the second distance d2 may be alternately arranged along the third direction Y to form a zigzag pattern. Each of the word lines WL which are alternately arranged may extend in the first direction X. The bit line BL may extend in the third direction Y, and a shape of the bit line BL is not limited to that shown in FIG. 2A. The source SO and the drain DR may be respectively located at a first end and a second end of the channel layer CH. The source SO and the drain DR corresponding to each other may be arranged in the vertical direction that is the second direction Z, to form a vertical channel transistor together with the channel layer CH. The buried contact BC may be located on the drain DR in the second direction Z to contact the drain DR, and the capacitor 200 may be located on the buried contact BC in the second direction Z. In embodiments of the present inventive concept, the direct contact DC may be formed in a portion of the bit line BL contacting the source SO. For example, the semiconductor memory device 1 may include a plurality of buried contacts BC and a plurality of direct contacts DC. The plurality of buried contacts BC may be located between the plurality of channel layers CH and the plurality of capacitors 200 and may be electrically connected to the channel layers CH. The plurality of direct contacts DC may be spaced apart from the buried contacts BC with the channel layers CH therebetween, and the direct contacts DC may be electrically connected to the channel layers CH and the bit lines BL. The plurality of bit lines BL may be electrically connected to one of the ends of the plurality of channel layers CH in the second direction Z. One pair of bit lines BL may be electrically connected to the channel layers CH located in different columns from among the channel layers CH. A method in which current flows through the channel layer CH only when a voltage is applied to the word lines WL located at both ends of the channel layer CH in the third direction Y will be described in detail with reference to FIG. 7.

The word line WL, the channel layer CH located at an intersection between the word line WL and the bit line BL, and the gate insulating layer 100a located between the word line WL and the channel layer CH may constitute a transistor.

FIG. 2B is a cross-sectional view illustrating a stacking structure semiconductor memory device in which word lines are arranged in a zigzag pattern, according to embodiment of the present inventive concept.

Portions that are structurally the same as those in FIG. 2A will not be described. Referring to FIG. 2B, the semiconductor memory device 1 may include a plurality of word lines WL, the bit lines BL, the channel layers CH, and the capacitors 200.

A distance between the word line WL and the bit line BL in the third direction Y may be the first distance d1 or the second distance d2. The first distance d1 and the second distance d2 may be different from each other, and the first distance d1 may be shorter than the second distance d2. In other words, a distance between some of the plurality of word lines WL and the bit line BL in the third direction Y may be the first distance d1, and a distance between some others of the plurality of word lines WL and the bit line BL in the third direction Y may be the second distance d2. The word line WL of which a distance in the third direction Y is the first distance d1 and the word line WL of which a distance in the third direction Y is the second distance d2 may be alternately arranged along the second direction Z to form a zigzag pattern. Each of the word lines WL which are alternately arranged may extend in the first direction X. The bit line BL may extend in the second direction Z, and a shape of the bit line BL is not limited to that shown in FIG. 2B. The source SO and the drain DR may be located at ends of the channel layer CH. The source SO and the drain DR corresponding to each other may be arranged in a horizontal direction that is the third direction Y, to form a vertical channel transistor together with the channel layer CH. The buried contact BC may be located on the drain DR in the third direction Y to contact the drain DR, and the capacitor 200 may be located on the buried contact BC in the third direction Y. In embodiments of the present inventive concept, the direct contact DC may be formed in a portion of the bit line BL to contact the source SO. For example, the semiconductor memory device 1 may include a plurality of buried contacts BC and a plurality of direct contacts DC. The plurality of buried contacts BC may be located between the plurality of channel layers CH and the plurality of capacitors 200, and may be electrically connected to the channel layers CH. The plurality of direct contacts DC may be spaced apart from the buried contacts BC with the channel layers CH therebetween and may be electrically connected to the channel layers CH and the bit lines BL. The plurality of bit lines BL may be electrically connected to one of the ends of the plurality of channel layers CH in the third direction Y. One pair of bit lines BL may be electrically connected to the channel layers CH that are located in different columns from among the channel layers CH. A method in which current flows through the channel layer CH only when a voltage is applied to the word lines WL at both ends of the channel layer CH in the second direction Z will be described in detail with reference to FIG. 7.

The word line WL, the channel layer CH that is located at an intersection between the word line WL and the bit line BL, and the gate insulating layer 100a that is located between the word line WL and the channel layer CH may constitute a transistor.

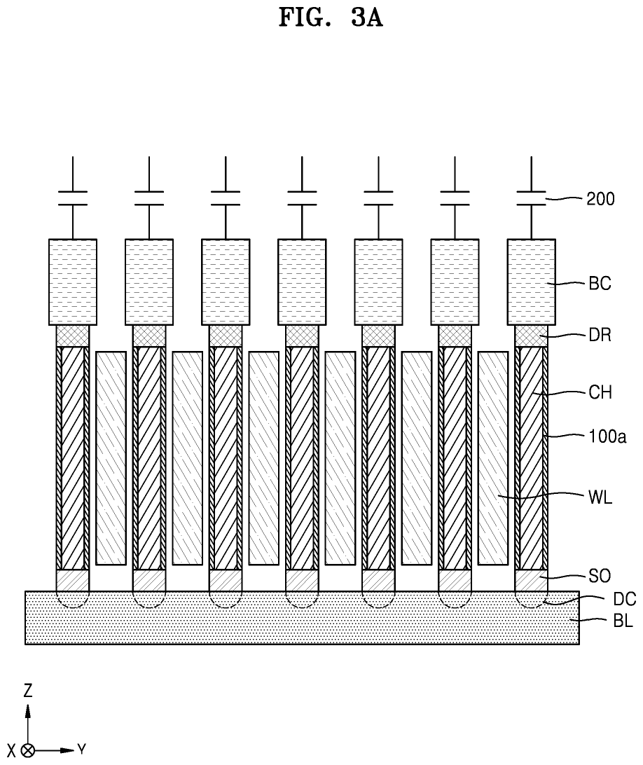

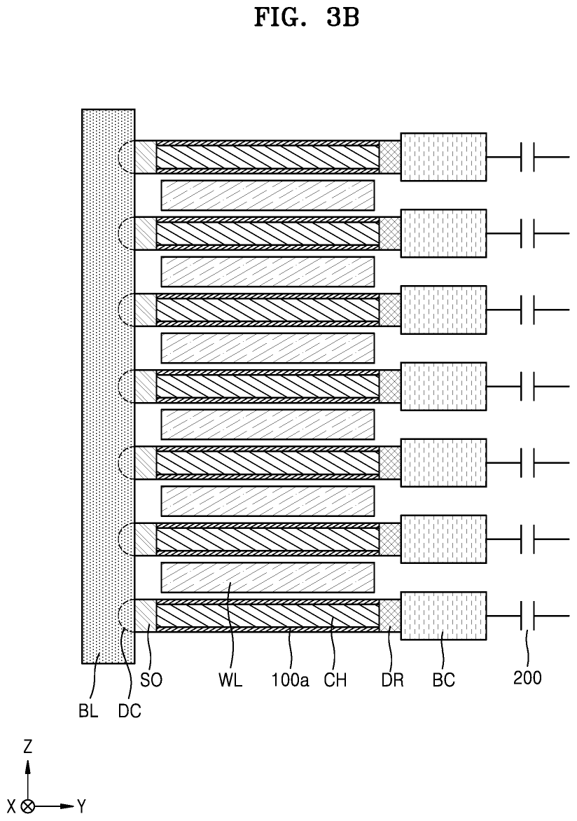

FIG. 3A is a cross-sectional view illustrating a vertical structure semiconductor memory device, according to embodiments of the present inventive concept.

FIG. 3B is a cross-sectional view illustrating a stacking structure semiconductor memory device, according to embodiments of the present inventive concept.

Referring to FIG. 3A, the first direction X and the third direction Y are horizontal directions that are parallel to a top surface of the semiconductor substrate 10 of FIG. 1, and the second direction Z is a vertical direction that is substantially perpendicular to the top surface of the semiconductor substrate 10. The word line WL may be alternately arranged with the channel layer CH in the third direction Y. The word line WL may extend in the first direction X, and a plurality of word lines WL may extend to the same length as each other in the second direction Z.

Referring to FIG. 3B, the word lines WL may be alternately arranged with the channel layer CH in the second direction Z. The word line WL may extend in the first direction X, and a plurality of word lines WL may extend to the same length in the third direction Y.

The plurality of word lines WL may include: a plurality of selected word lines to which a positive voltage is applied; and a plurality of non-selected word lines to which a negative voltage is applied.

The plurality of channel layers CH may include a selected channel layer that is turned on and a non-selected channel layer that is turned off. One pair of word lines WL adjacent to ends of a selected channel layer may be selected word lines, and at least one of one pair of word lines WL adjacent to ends of a non-selected channel layer may be a non-selected word line. The adjacent direction may be the second direction Z or the third direction Y.

A positive voltage or a negative voltage may be applied to the word line WL to determine whether current flows through the channel layer CH, and the positive voltage may be about 3 V and the negative voltage may range from about −0.4 V to about −1.0 V. When a positive voltage is applied to the word line WL, current may flow through the channel layers CH at both ends in the third direction Y, and thus, the word line WL may adjust whether current flows through at least one channel layer CH in the third direction Y. When the word line WL applies a positive voltage, it may affect the channel layer CH through which current does not flow. Accordingly, one of the word lines WL adjacent to the non-selected channel layer CH through which current does not flow in the third direction Y may be a non-selected word line that applies a negative voltage. When the non-selected word line applies a negative voltage, cell leakage control may be performed for the adjacent channel layer CH. A value of current flowing from the source SO to the drain DR in a selected channel layer may be 1E-06A; a value of current flowing from the source SO to the drain DR may be 1E-10A when a negative voltage of a non-selected word line in a non-selected channel layer is −0.4 V; a value of current flowing from the source SO to the drain DR may be 1E-12A when a negative voltage of a non-selected word line in a non-selected channel layer is −0.6 V; a value of current flowing from the source SO to the drain DR may be 1E-14A when a negative voltage of a non-selected word line in a non-selected channel layer is −0.8 V; a value of current may be 1E-16A when a negative voltage of a non-selected word line in a non-selected channel layer is −1.0 V; and a current ratio between an adjacent selected channel and an adjacent non-selected channel may be equal to or greater than, or equal to or less than 1E+10. However, the present inventive concept is not limited thereto.

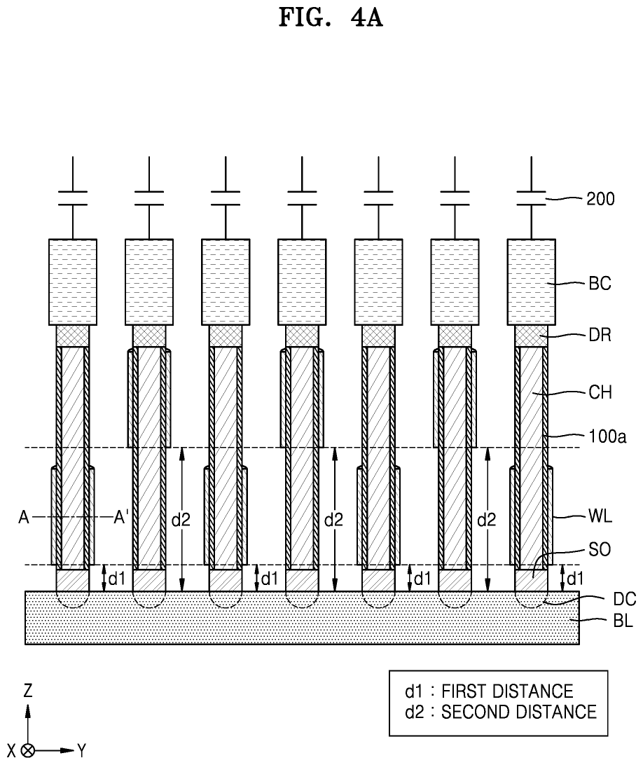

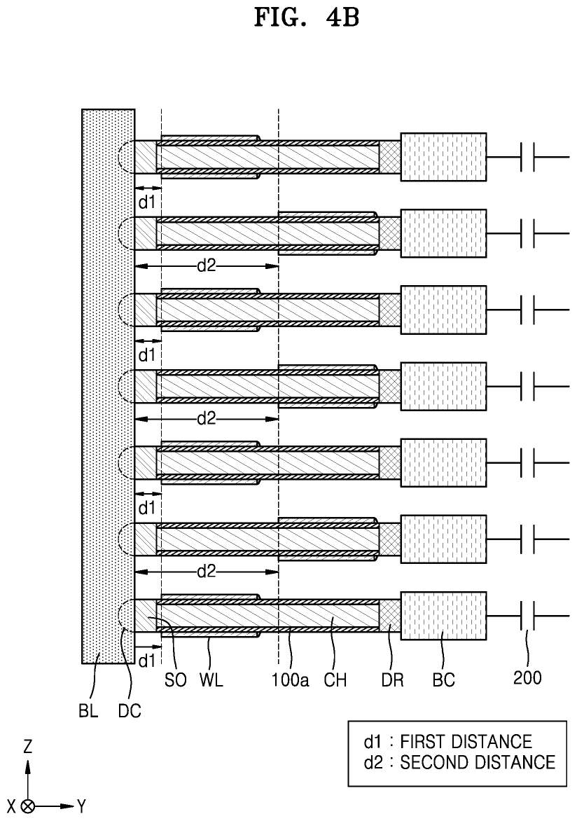

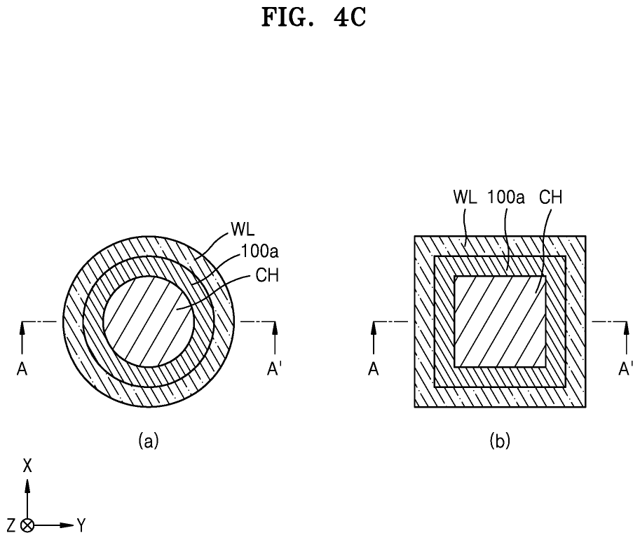

FIG. 4A is a cross-sectional view illustrating a vertical structure semiconductor memory device in which word lines are arranged in a gate-all-around shape in a zigzag pattern, according to embodiments of the present inventive concept.

Referring to FIG. 4A, the first direction X and the third direction Y are horizontal directions that are parallel to a top surface of the semiconductor substrate 10 of FIG. 1, and the second direction Z is a vertical direction that is substantially perpendicular to the top surface of the semiconductor substrate 10 of FIG. 1. A plurality of word lines WL may extend while surrounding outer circumferential surfaces of a plurality of channel layers CH to surround at least a portion of the plurality of channel layers CH, and the surrounded portion may be a part or the whole, but the present inventive concept is not limited thereto. The plurality of word lines WL may include a plurality of selected word lines to which a positive voltage is applied and a plurality of non-selected word lines to which a negative voltage is applied, and the plurality of channel layers CH may include a selected channel layer that is turned on and a non-selected channel layer that is turned off.

The word line WL extending to surround an outer circumferential surface of a selected channel layer may be a selected word line, and the word line WL extending to surround an outer circumferential surface of a non-selected channel layer may be a non-selected word line.

A distance between the plurality of word lines WL and the bit line BL in the second direction Z may be the first distance d1 or the second distance d2. The first distance d1 and the second distance d21 may be different from each other, and the first distance d1 may be shorter than the second distance d2. In other words, a distance between some of the plurality of word lines WL and the bit line BL in the second direction Z may be the first distance d1, and a distance between some others of the plurality of word lines WL and the bit line BL in the second direction Z may be the second distance. The word line WL of which a distance in the second direction Z is the first distance d1 and the word line WL of which a distance in the second direction Z is the second distance d2 may be alternately arranged with each other along the third direction Y and may extend in a zigzag pattern. Each of the word lines WL which are alternately arranged may extend in the first direction X. The bit line BL may extend in the third direction Y, and a shape of the bit line BL is not limited to that shown in FIG. 4A.

The word lines WL which are alternately arranged may surround an outer circumferential surface of the channel layer CH. For example, the word line WL may surround the gate insulating unit 100a that is surrounding the channel layer CH, and a thickness of the word line WL may vary according to the amount of current flowing through the channel layer CH, but the present inventive concept is not limited thereto. The bit line BL may extend in the third direction Y, and a shape of the bit line BL is not limited to that shown in FIG. 4A. The source SO and the drain DR may be located at ends of the channel layer CH, and the source SO and the drain DR may be arranged in a vertical direction that is the second direction Z to form a vertical channel transistor.

FIG. 4B is a cross-sectional view illustrating a stacking structure semiconductor memory device in which word lines are arranged in a gate-all-around shape in a zigzag pattern, according to embodiments of the present inventive concept.

Portions that are structurally the same as those in FIG. 4A will not be described. Referring to FIG. 4B, a distance between the word line WL and the bit line BL in the first direction Y may be the first distance d1 or the second distance d2. The first distance d1 and the second distance d2 may be different from each other, and the first distance d1 may be shorter than the second distance d2. In other words, a distance between some of the plurality of word lines WL and the bit line BL in the third direction Y may be the first distance d1, and a distance between some others of the plurality of word lines WL and the bit line BL in the third direction Y may be the second distance d2. The word line WL of which a distance in the third direction Y is the first distance d1 and the word line WL of which a distance in the third direction Y is the second distance d2 may be alternately arranged with each other along the second direction Z and may extend in a zigzag pattern. Each of the word lines WL which are alternately arranged may extend in the first direction X. The bit line BL may extend in the second direction Z, and a shape of the bit line BL is not limited to that shown in FIG. 4B. The word lines WL which are alternately arranged may surround an outer circumferential surface of the channel layer CH. In more detail, the word line WL may surround the gate insulating unit 100a surrounding the channel layer CH, and a thickness of the word line WL may vary according to the amount of current flowing through the channel layer CH, but the inventive concept is not limited thereto. The bit line BL may extend in a vertical direction that is the second direction Z, and a shape of the bit line BL is not limited to that shown in FIG. 4B. The source SO and the drain DR may be arranged at both ends of the channel layer CH, and the source SO and the drain DR may be arranged in a horizontal direction that is the third direction Y to form a stacking channel transistor.

FIG. 4C is a cross-sectional view taken along line A-A′ of FIG. 4A.

Referring to FIG. 4C, the channel layer CH, the gate insulating layer 100a, and the word line WL may be sequentially arranged outward. The gate insulating layer 100a may surround an outer circumferential surface of the channel layer CH, and the word line WL may surround an outer circumferential surface of the gate insulating layer 100a. A thickness of each of the channel layer CH, the gate insulating layer 100a, and the word line WL is not limited, and may vary according to the amount of current flowing through the channel layer CH or the amount of voltage of the word line WL that is applied to cause current to flow through the channel layer CH.

Each of the channel layer CH, the gate insulating layer 100a, and the word line WL may have a circular cross-sectional shape as shown in (a), a quadrangular cross-sectional shape as shown in (b), or a polygonal cross-sectional shape such as a triangular shape or a pentagonal shape, but the present inventive concept is not limited thereto.

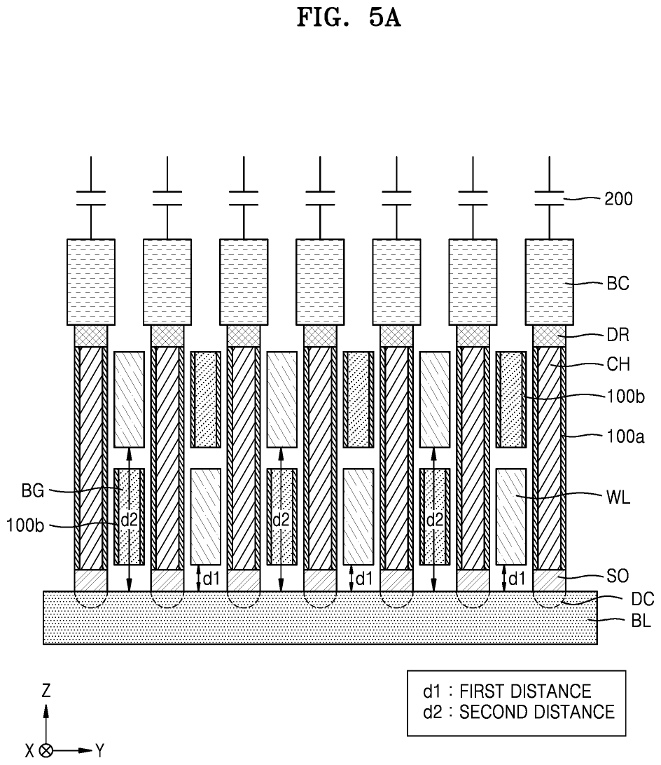

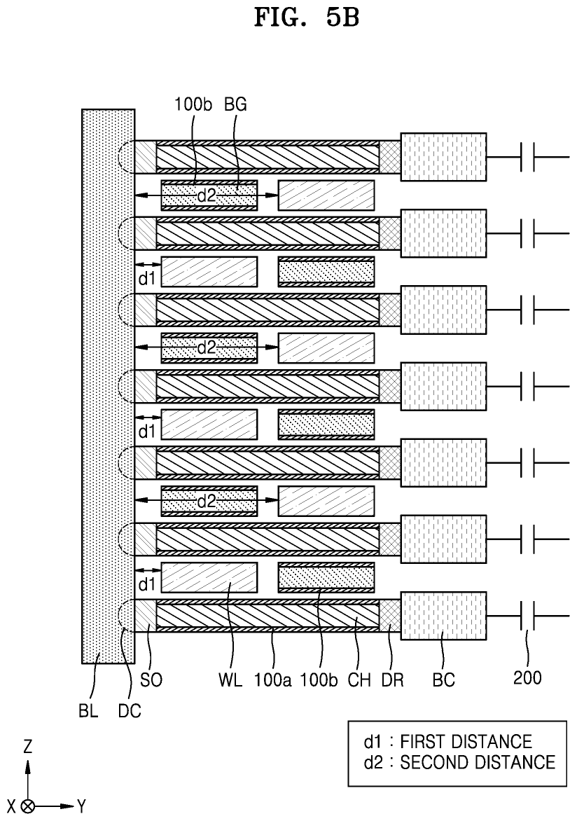

FIG. 5A is a cross-sectional view illustrating a vertical structure semiconductor memory device in which word lines and back gates are arranged in a zigzag pattern, according to embodiments of the present inventive concept.

Referring to FIG. 5A, the first direction X and the third direction Y are horizontal directions that are parallel to a top surface of the semiconductor substrate 10 of FIG. 1, and the second direction Z is a vertical direction that is substantially perpendicular to the top surface of the semiconductor substrate 10 of FIG. 1. The semiconductor memory device may include a plurality of back gates BG, which extend in the first direction X between a plurality of channel layers CH, a plurality of gate insulating layers 100a, which surround the plurality of channel layers CH, and a plurality of back gate insulating layers 100b, which cover side surfaces of the plurality of back gates BG and extend in the first direction X. The plurality of gate insulating layers 100a may surround at least a portion or the whole of the plurality of channel layers CH in a plan view, and a thickness of the back gate insulating layer 100b may vary according to the amount of current and the amount of voltage, but the present inventive concept is not limited thereto.

A distance between each of at least two of the plurality of back gates BG and the bit lines BL in the second direction Z may be the first distance d1 or the second distance d2. The back gate BG of which a distance in the second direction Z is the first distance d1 and the back gate BG of which a distance in the second direction Z is the second distance d2 may be alternately arranged with each other to form a zigzag pattern. A distance between each of at least two of the plurality of word lines WL and the bit lines BL in the second direction Z may be the first distance d1 or the second distance d2. The word line WL of which a distance in the second direction Z is the first distance d1 and the back gate BG of which a distance in the second direction Z is the second distance d2, and the word line WL of which a distance in the second direction Z is the second distance d2 and the back gate BG of which a distance in the second direction Z is the first distance d1 may each extend as a pair, and the first distance d1 may be shorter or longer than the second distance d2, but the present inventive concept is not limited thereto.

The back gate insulating layer 100b may be formed of at least one of, for example, silicon oxide, silicon nitride, silicon oxynitride, oxide/nitride/oxide (ONO), and/or a high-k dielectric material having a dielectric constant that is higher than that of silicon oxide. For example, the back gate insulating layer 100b may have a dielectric constant of about 10 to about 25. A back gate line material layer may be formed of a semiconductor material, a metal material, a conductive metal nitride, or a combination thereof. In embodiments of the present inventive concept, the back gate line material layer may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The plurality of word lines WL may include: a plurality of selected word lines to which a positive voltage is applied; and a plurality of non-selected word lines to which a negative voltage is applied, and the plurality of channel layers CH may include a selected channel layer that is turned on and a non-selected channel layer that is turned off. The word lines WL may be adjacent to ends of a selected channel layer in the first direction Y may all be selected word lines, and at least one of the word lines WL that is adjacent to ends of a non-selected channel line in the third direction Y may be a non-selected word line.

A positive voltage or a negative voltage may be applied to the word line WL to determine whether current flows through the channel layer CH, and the positive voltage may be 3 V and the negative voltage may range from −0.4 V to −1.0 V. When a positive voltage is applied to the word line WL, current may flow through the channel layers CH at ends thereof in the third direction Y, and thus, the word line WL may adjust whether current flows through at least one channel layer CH in the third direction Y. When the word line WL applies a positive voltage, it may affect the channel layer CH through which current does not flow. Accordingly, one of the word lines WL adjacent to the non-selected channel layer CH through which current does not flow in the third direction Y may be a non-selected word line that applies a negative voltage. When the non-selected word line applies a negative voltage, cell leakage control may be performed for the adjacent channel layer CH. In addition, like a non-selected word line, for a selected word line not to be affected by a non-selected channel adjacent in the third direction Y, the plurality of back gates BG may perform a function of controlling disturbance together with the non-selected word line.

FIG. 5B is a cross-sectional view illustrating a stacking structure semiconductor memory device in which word lines and back gates are arranged in a zigzag pattern, according to embodiments of the present inventive concept.

Portions that are structurally the same as those in FIG. 5A will not be described. Referring to FIG. 5B, the semiconductor memory device may include a plurality of back gates BG, which extend in the third direction Y between the plurality of channel layers CH, a plurality of gate insulating layers 100a, which surround the plurality of channel layers CH, and a plurality of back gate insulating layers 100b, which cover side surfaces of the plurality of back gates BG and extend in the third direction Y. A distance between each of at least two of the plurality of back gates BG and the bit lines BL in the third direction Y may be the first distance d1 or the second distance d2. The back gate BG of which a distance in the third direction Y is the first distance d1 and the back gate BG of which a distance in the second direction Z is the second distance d2 may be alternately arranged with each other and may extend in a zigzag pattern. A distance between each of at least two of the plurality of word lines WL and the bit line BL in the third direction Y may be the first distance d1 or the second distance d2. The word line WL of which a distance in the third direction Y is the first distance d1 and the back gate BG of which a distance in the third direction Y is the second distance d2, and the word line WL of which a distance in the second direction Z is the second distance d2 and the back gate BG of which a distance in the third distance Y is the first distance d1 may each extend as a pair, and the first distance d1 may be shorter or longer than the second distance d2, but the present inventive concept is not limited thereto.

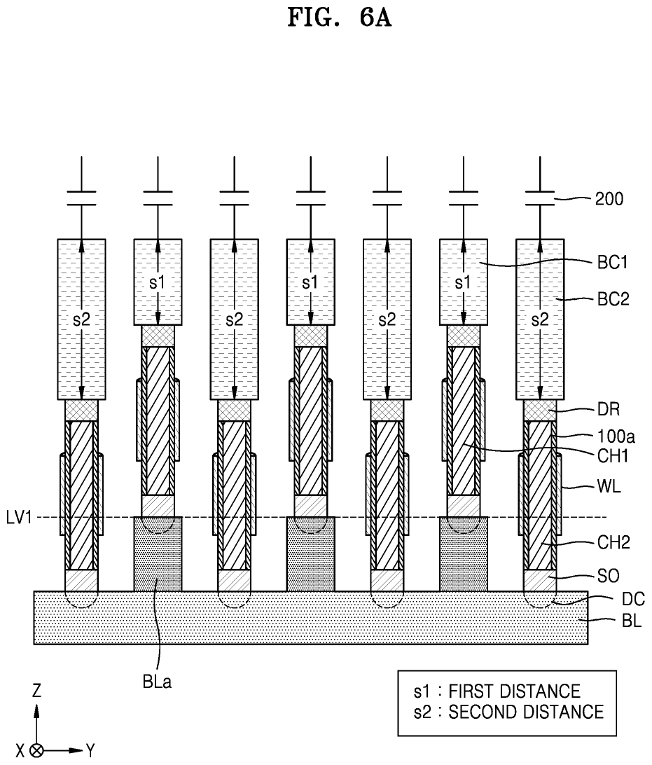

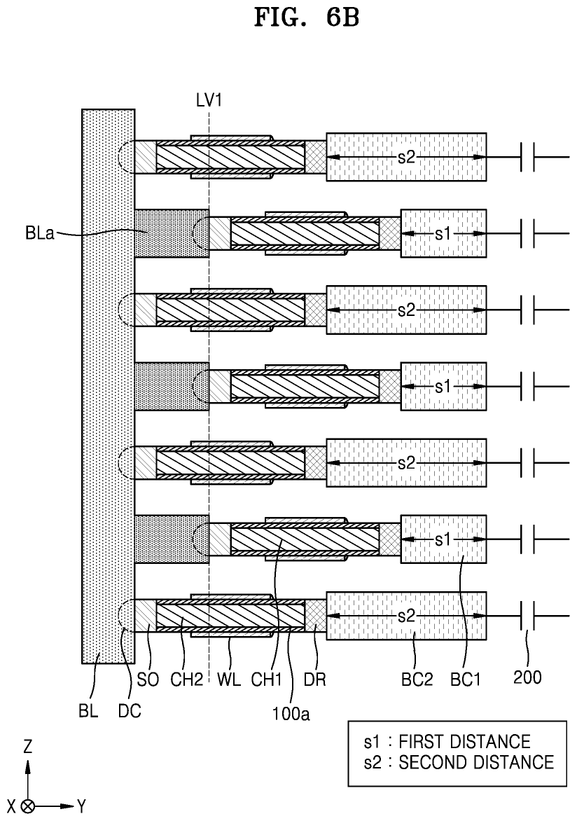

FIG. 6A is a cross-sectional view illustrating a vertical structure semiconductor memory device in which word lines and back gates are arranged in a zigzag pattern, according to embodiments of the present inventive concept.

Referring to FIG. 6A, the first direction X and the third direction Y are horizontal directions that are parallel to a top surface of the semiconductor substrate 10 of FIG. 1, and the second direction Z is a vertical direction that is substantially perpendicular to the top surface of the semiconductor substrate 10 of FIG. 1. A plurality of word lines WL may extend to surround outer circumferential surfaces of a plurality of channel layers CH to surround at least a portion of the plurality of channel layers CH, and the surrounded portion may be a part or the whole, but the present inventive concept is not limited thereto. The plurality of word lines WL may include a plurality of selected word lines to which a positive voltage is applied and a plurality of non-selected word lines to which a negative voltage is applied, and the plurality of channel layers CH may include a selected channel layer that is turned on and a non-selected channel layer that is turned off. For a selected channel layer, the word line WL extending to surround an outer circumferential surface of the channel layer CH may be a selected word line, and for a non-selected channel layer, the word line WL extending to surround an outer circumferential surface of the channel layer CH may be a non-selected word line.

The plurality of channel layers CH may include a plurality of first channel layers CH1 and a plurality of second channel layers CH2, and the plurality of first channel layers CH1 and the second channel layers CH2 may be alternately arranged with each other. The semiconductor memory device may further include a bit line extension unit BLa that is located between the first channel layer CH1 and the bit line BL and that extends to a first level LV1 in the second direction Z, and the first level LV1 may vary according to the amount of current or the amount of voltage and is not limited to that shown FIG. 6A. In other words, the semiconductor memory device may include a plurality of bit line extension units BLa that are located in at least a portion of intersections of the plurality of first channel layers CH1 and the plurality of bit lines BL and that extend from the plurality of bit lines BL to the first level LV1 in the second direction Z.

A plurality of buried contacts BC may further include a plurality of first buried contacts BC1, which correspond to the plurality of first channel layers CH1, and a plurality of second buried contacts BC2, which correspond to the plurality of second channel layers CH2. A length of the plurality of first buried contacts BC1 that extend in the second direction Z may be a first length s1, and a length of the plurality of second buried contacts BC2 that extend in the second direction Z may be a second length s2. The first length s1 may be shorter than the second length s2, but the present inventive concept is not limited thereto.

The plurality of word lines WL may have the same distance from the plurality of first buried contacts BC1 and the plurality of second buried contacts BC2 in the second direction Z, and may have the same distance from a plurality of direct contacts DC in the second direction Z, but the present inventive concept is not limited thereto.

FIG. 6B is a cross-sectional view illustrating a stacking structure semiconductor memory device in which word lines and back gates are arranged in a zigzag pattern, according to embodiments of the present inventive concept.

Portions that are structurally the same as those in FIG. 6A will not be described. Referring to FIG. 6B, a plurality of channel layers CH may include a plurality of first channel layers CH1 and a plurality of second channel layers CH21, and the plurality of first channel layers CH1 and the plurality of second channel layers CH2 may be alternately arranged with each other in a vertical direction that is the second direction Z. The semiconductor memory device may further include the bit line extension unit BLa that is located between the first channel layer CH1 and the bit line BL and that extends to the first level LV1 in the third direction Y, and the first level LV1 may vary according to the amount of current or the amount of voltage, but the present inventive concept is not limited thereto. A length of the plurality of first buried contacts BC2 in the third direction Y may be the first length s1, and a length of the plurality of second buried contacts BC2 in the third direction Y may be the second length s2. The first length s1 may be shorter than the second length s2, but the present inventive concept is not limited thereto.

A plurality of word lines WL may have the same distance from the plurality of first buried contacts BC1 and the plurality of second buried contacts BC2 in the third direction Y, and may have the same distance from a plurality of direct contacts DC in the third direction Y, but the present inventive concept is not limited thereto.

The source SO and the drain DR may be located at ends (e.g., opposing ends) of the channel layer CH, and the source SO and the drain DR may be arranged in a horizontal direction that is the third direction Y to form a stacking channel transistor, but the present inventive concept is not limited thereto.

FIG. 7 is a view illustrating an operating method of a semiconductor memory device, according to embodiments of the present inventive concept.

A plurality of word lines WL may include a selected word line WLa that is turned on to apply a positive voltage to the channel layers CH adjacent to both ends in the third direction Y, and a non-selected word line WLb that is turned off to apply a negative voltage to the channel layers CH adjacent to both ends in the third direction Y. A plurality of channel layers CH may include a selected channel layer CHa that is turned on and through which current flows, and a non-selected channel layer CHb that is turned off and through which current does not flow. The selected channel layer CHa may allow current to flow through the buried contact BC that is adjacent to the drain DR, to electrically connect the bit line BL to the capacitor 200. Referring to FIG. 7, only a third capacitor 200 may be electrically connected to the bit line BL, and signals of 0^{th} to 2^{nd} and 4^{th} to 6^{th} capacitors 200 might not be electrically connected to the bit line BL.

The word lines WL that are adjacent to ends of the selected channel layer CHa in the third direction Y should all be the selected word lines WLa, and at least one of the word lines WL that is adjacent to ends of the non-selected channel layer CHb in the third direction Y should be the non-selected word line WLb. Referring to FIG. 7, the channel layers CH connected to the 0^{th} and 6^{th} capacitors 200 correspond to the non-selected channel layers CHb because the word lines WL that are adjacent in the third direction Y are the non-selected word lines WLb, and the channel layers CH that are connected to the first and fifth capacitors 200 correspond to the non-selected channel layers CHb because the word lines WL adjacent to sides in the third direction Y are all the non-selected word lines WLb. The channel layers CH that are connected to the second and fourth capacitors 200 correspond to the non-selected channel layers CHb because one of the word lines WL that is adjacent to sides in the third direction Y is the selected word line WLa but the other word line WL corresponds to the non-selected word line WLb and thus the flow of current in a vertical direction that is the second direction Z of the channel layer CH is stopped, and the channel layer CH that is connected to the third capacitor 200 corresponds to the selected channel layer CHa because the word lines WL that are adjacent to both sides in the third direction Y are all the selected word lines WLa and current may flow to the capacitor 200.

The selected word line WLa that is located between the channel layers CH that are connected to the second and third capacitors 200 might not only apply a positive voltage to the channel layers CH adjacent to both ends in the third direction Y but may also disturb the channel layer CH that is connected to the fourth capacitor 200 and that is spaced apart from the selected word line WLa in the third direction Y. In more detail, although no signal should be input to the fourth capacitor 200, the channel layer CH connected to the fourth capacitor 200 may be disturbed by the selected word line WLa located between the channel layers CH that are connected to the second and third capacitors 200 and a signal may be input to the channel layer CH that is connected to the fourth capacitor 200 by the selected word line WLa that is located between the channel layers CH that are connected to the third and fourth capacitors 200. The non-selected word line WLb that is located between the channel layers CH that are connected to the fourth and fifth capacitors 200 may apply a negative voltage to control such disturbance.

The selected word line WLa that is located between the channel layers CH that are connected to the third and fourth capacitors 200 might not only apply a positive voltage to the channel layers CH that are adjacent to both ends in the third direction Y but may also disturb the channel layer CH that is connected to the second capacitor 200 and that is spaced apart from the selected word line WLa in the third direction Y. For example, although no signal should be input to the second capacitor 200, the channel layer CH that is connected to the second capacitor 200 may be disturbed by the selected word line WLa that is located between the channel layers CH that are connected to the third and fourth capacitors 200 and a signal may be input to the channel layer CH that are connected to the second capacitor 200 by the selected word line WLa that is located between the channel layers CH that are connected to the second and third capacitors 200. The non-selected word line WLb that is located between the channel layers CH that are connected to the first and second capacitors 200 may apply a negative voltage to control such disturbance. Due to the negative voltage applied by the non-selected word line WLb, the flow of current through the channel layer CH corresponding to the same position as the corresponding word line WL in the second direction Z may be blocked. A position in the second direction Z which blocks the flow of current is not limited thereto, and may be changed. For example, a positive voltage may be about 3 V, and a negative voltage may range from about −0.4 V to about −1.0 V. When a positive voltage is applied to the word line WL, current may flow through the channel layers CH at both ends in the third direction Y. Accordingly, the word line WL may adjust whether current flows through at least one channel layer CH in the third direction Y. When the non-selected word line WLb applies a negative voltage, cell leakage control may be performed for the adjacent channel layer CH. A value of current flowing from the source SO to the drain DR in the selected channel layer CHa may be about 1E-06A; a value of current may be about 1E-10A when a negative voltage of the non-selected word line WLb in the non-selected channel layer CHb is about −0.4 V; a value of current may be about 1E-12A when a negative voltage of the non-selected word line WLb in the non-selected channel layer CHb is about −0.6 V; a value of current may be about 1E-14A when a negative voltage of the non-selected word line WLb in the non-selected channel layer CHb is about −0.8 V; a value of current may be about 1E-16A when a negative voltage of the non-selected word line WLb in the non-selected channel layer CHb is about −1.0 V; and a current ratio between an adjacent selected channel layer CHa and an adjacent non-selected channel layer CHb may be equal to or greater than, or equal to or less than about 1E+10. However, the present inventive concept is not limited thereto.

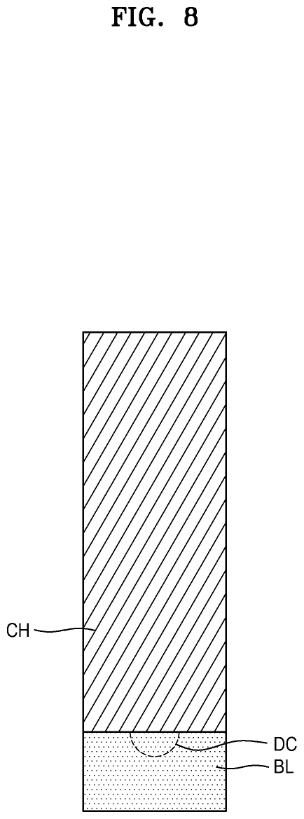

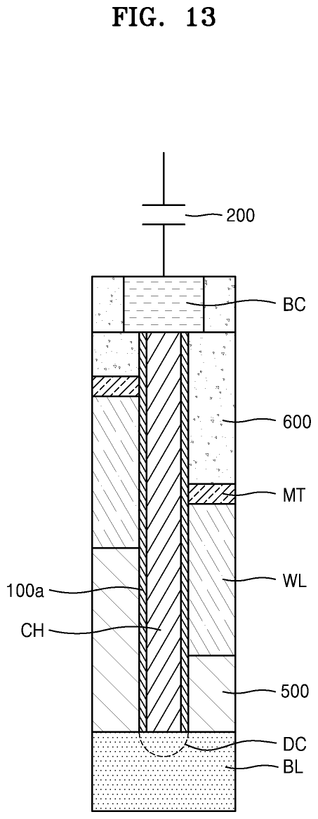

FIGS. 8 to 13 are views sequentially illustrating a process of a semiconductor memory device, according to embodiments of the present inventive concept.

Referring to FIGS. 8 to 13, referring to FIG. 8, the bit line BL may be formed, and the direct contact DC may be formed in a portion of the bit line BL. The channel layer CH may be stacked on the bit line BL.

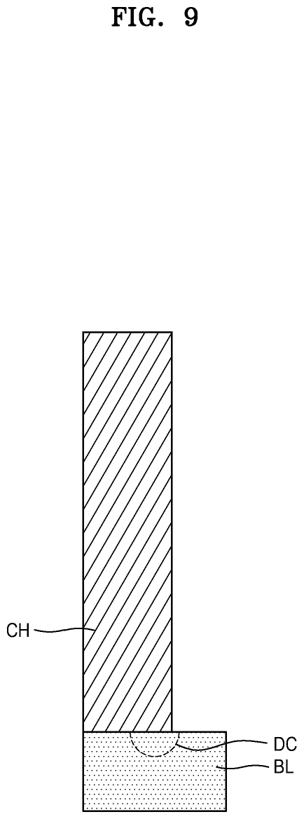

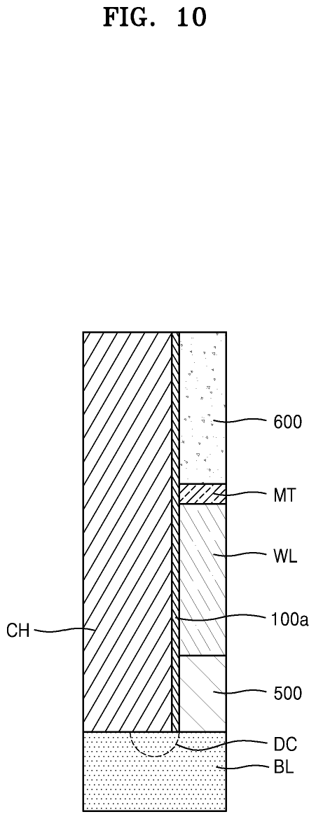

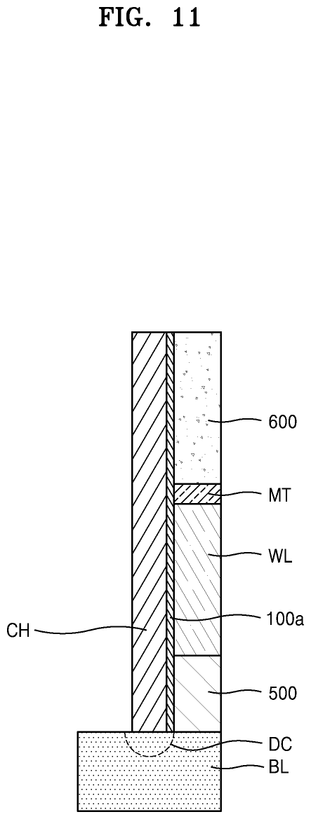

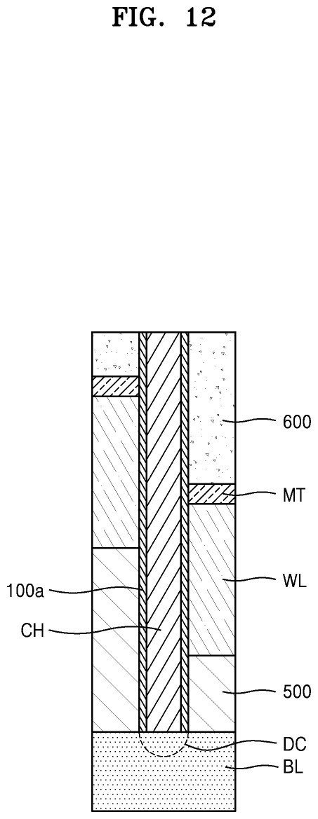

Referring to FIG. 9, a portion of the channel layer CH in the third direction Y may be etched in an etching process to form a space in which the word line WL is located. An etched position or thickness is not limited to that shown in FIG. 9. Referring to FIG. 10, a height adjustment insulator 500 may be stacked in the second direction Z to determine a position of the word line WL with respect to the etched portion, and the word line WL may be stacked in the second direction Z. A metal layer MT may be formed on the word line WL, and an insulator 600 may be stacked on the metal layer MT. Referring to FIG. 11, a portion of the other side, which is spaced apart from and opposite in the first direction Y to the etched portion for the word line WL may be etched. An etched position or thickness is not limited to that shown in FIG. 11. Referring to FIG. 12, the height adjustment insulator 500 may be stacked in the second direction Z to determine a position of the word line WL with respect to the etched portion, and a stacked height may be higher or lower than that of the height adjustment insulator 500 spaced apart in the third direction Y, but the present inventive concept is not limited thereto. The word line WL may be stacked on the height adjustment insulator 500 in the second direction Z, and the word line WL may be a lower gate or an upper gate according to a height of the height adjustment insulator 500 formed in the second direction Z, but the present inventive concept is not limited thereto. The metal layer MT may be formed on the word line WL in the second direction Z, and the insulator 600 may be stacked on the metal layer MT in the second direction Z. The insulator 600 may be stacked to the same level as the insulator 600 stacked on one side in the second direction Z, and heights may be different, but the present inventive concept is not limited thereto. The buried contact BC may be formed on the stacked channel layer CH, and the capacitor 200 may be formed. The direct contact DC may be formed at a portion where the bit line BL and the channel layer CH contact each other.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor memory device comprising:
a plurality of word lines extending in a first direction;
a plurality of channel layers alternately arranged with the plurality of word lines, wherein the plurality of channel layers extend in a second direction that crosses the first direction; and
a plurality of bit lines located on the plurality of word lines and the plurality of channel layers, and extending in a third direction crossing to the first direction and the third direction, and wherein the plurality of bit lines are electrically connected to the plurality of channel layers,
wherein the plurality of word lines comprise: a plurality of selected word lines to which a positive voltage is applied; and a plurality of non-selected word lines to which a negative voltage is applied, and
the plurality of channel layers comprise: a selected channel layer that is turned on; and a non-selected channel layer that is turned off,
wherein one pair of word lines adjacent to ends of the selected channel layer are all the selected word lines, and
at least one of one pair of word lines adjacent to ends of the non-selected channel layer are each one of the non-selected word lines.

2. The semiconductor memory device of claim 1, wherein
the first direction and the third direction are horizontal directions that are parallel to a top surface of a semiconductor substrate, and
the second direction is a vertical direction that is perpendicular to the top surface of the semiconductor substrate,
wherein the semiconductor memory device further comprises a plurality of sources and a plurality of drains located on the plurality of channel layers,
wherein the plurality of word lines, the plurality of channel layers, the plurality of sources, and the plurality of drains constitute a vertical channel transistor.

3. The semiconductor memory device of claim 1, wherein a distance between each of at least two of the plurality of word lines and the bit lines in the second direction is a first distance or a second distance, and a word line of which a distance in the second direction is the first distance and a word line of which a distance in the second direction is the second distance are alternately arranged with each other to form a zigzag pattern,
wherein the first distance is shorter than the second distance.

4. The semiconductor memory device of claim 1, further comprising a plurality of capacitors electrically connected to the plurality of channel layers.

5. The semiconductor memory device of claim 4, further comprising:
a plurality of buried contacts located between the plurality of channel layers and the plurality of capacitors, and electrically connected to the plurality of channel layers; and
a plurality of direct contacts spaced apart from the plurality of buried contacts with the plurality of channel layers disposed therebetween, and electrically connecting the plurality of channel layers to the plurality of bit lines.

6. The semiconductor memory device of claim 1, further comprising:
a plurality of back gates extending in the first direction between the plurality of channel layers;
a plurality of gate insulating layers at least partially surrounding the plurality of channel layers; and
a plurality of back gate insulating layers covering side surfaces of the plurality of back gates and extending in the first direction.

7. The semiconductor memory device of claim 6, wherein the plurality of gate insulating layers surround at least a portion of the plurality of channel layers.

8. The semiconductor memory device of claim 6, wherein a distance between each of at least two of the plurality of back gates and the bit lines in the second direction is a first distance or a second distance, wherein a back gate of which a distance in the second direction is the first distance and a back gate of which a distance in the second direction is the second distance are alternately arranged with each other to form a zigzag pattern,
a distance between each of at least two of the plurality of word lines and the bit lines in the second direction is the first distance or the second distance, and
a word line of which a distance in the second direction is the first distance and a back gate of which a distance in the second direction is the second distance, and a word line of which a distance in the second direction is the second distance and a back gate of which a distance in the second direction is the first distance each extend as a pair,
wherein the first distance is shorter than the second distance.

9. The semiconductor memory device of claim 1, further comprising a peripheral circuit structure comprising a plurality of peripheral circuits,
wherein the plurality of bit lines are located between the plurality of channel layers and the peripheral circuit structure.

10. The semiconductor memory device of claim 1, wherein each of the plurality of word lines comprises at least one of a metal, a semiconductor, or an alloy.

11. A semiconductor memory device comprising:
a plurality of channel layers arranged in a first direction and extending in a second direction that is substantially perpendicular to the first direction;
a plurality of word lines extending while surrounding at least a portion of outer circumferential surfaces of the plurality of channel layers;
a plurality of bit lines located on the plurality of word lines and the plurality of channel layers, and extending in a third direction perpendicular to the first direction and the second direction, wherein the plurality of bit lines are electrically connected to the plurality of channel layers; and
a plurality of capacitors electrically connected to the plurality of channel layers,
wherein the plurality of word lines comprise: a plurality of selected word lines to which a positive voltage is applied; and a plurality of non-selected word lines to which a negative voltage is applied, and
the plurality of channel layers comprise: a selected channel layer that is turned on; and a non-selected channel layer that is turned off,
wherein the word line surrounding at least a portion of an outer circumferential surface of the selected channel layer is one of the selected word lines, and
the word line surrounding at least a portion of an outer circumferential surface of the non-selected channel layer is one of the non-selected word lines.

12. The semiconductor memory device of claim 11, wherein a plurality of sources and a plurality of drains are provided at ends of the plurality of channel layers,
wherein the first direction and the third direction are horizontal directions that are parallel to a top surface of a semiconductor substrate, and
the second direction is a vertical direction that is substantially perpendicular to the top surface of the semiconductor substrate,
wherein the plurality of word lines, the plurality of channel layers, the plurality of sources, and the plurality of drains constitute a vertical channel transistor.

13. The semiconductor memory device of claim 11, wherein a distance between each of at least two of the plurality of word lines and the bit line in the second direction is a first distance or a second distance,
wherein a word line of which a distance in the second direction is the first distance and a word line of which a distance in the second direction is the second distance are alternately arranged with each other to form a zigzag pattern,
wherein the first distance is shorter than the second distance.

14. The semiconductor memory device of claim 11, further comprising:
a plurality of buried contacts located between the plurality of channel layers and the plurality of capacitors, and electrically connected to the plurality of channel layers; and
a plurality of direct contacts spaced apart from the plurality of buried contacts with the plurality of channel layers disposed therebetween, and electrically connecting the plurality of channel layers to the plurality of bit lines.

15. The semiconductor memory device of claim 14, wherein the plurality of channel layers comprise: a plurality of first channel layers; and a plurality of second channel layers,
wherein the plurality of first channel layers and the plurality of second channel layers are alternately arranged with each other in the third direction,
wherein the semiconductor memory device further comprises a plurality of bit line extension units located in at least a portion of intersections of the plurality of first channel layers and the plurality of bit lines, and extending from the plurality of bit lines to a first level in the second direction,
wherein the plurality of buried contacts comprise: a plurality of first buried contacts corresponding to the plurality of first channel layers and extending by a first length in the second direction; and a plurality of second buried contacts corresponding to the plurality of second channel layers and extending by a second length, greater than the first length, in the second direction.

16. The semiconductor memory device of claim 15, wherein the plurality of word lines have a same distance from the plurality of first buried contacts and the plurality of second buried contacts in the second direction, and have a same distance from the plurality of direct contacts in the second direction.

17. The semiconductor memory device of claim 11, wherein each of the plurality of non-selected word lines is configured to apply a negative voltage of about −0.6 V to about −1.0 V so that current does not flow through the non-selected channel layer due to the selected word line adjacent in the third direction.

18. The semiconductor memory device of claim 11, further comprising a plurality of gate insulating layers at least partially surrounding the plurality of channel layers,
wherein the plurality of gate insulating layers surround at least a portion of the plurality of channel layers.

19. The semiconductor memory device of claim 11, further comprising a peripheral circuit structure comprising a plurality of peripheral circuits,
wherein the plurality of bit lines are located between the plurality of channel layers and the peripheral circuit structure.

20. A semiconductor memory device comprising:
a plurality of vertical channel transistors; and
a plurality of capacitors electrically connected to the plurality of vertical channel transistors,
wherein the plurality of vertical channel transistors comprise:
a plurality of word lines extending in a first horizontal direction;
a plurality of channel layers alternately arranged with the plurality of word lines, and extending in a vertical direction that is substantially perpendicular to the first horizontal direction;
a plurality of gate insulating layers at least partially surrounding the plurality of channel layers;
a plurality of bit lines located on the plurality of word lines, the plurality of channel layers, and the plurality of gate insulating layers, and extending in a second horizontal direction that is substantially perpendicular to the first horizontal direction and the vertical direction, wherein the plurality of bit lines are electrically connected to the plurality of channel layers;
a plurality of buried contacts (BC) located between the plurality of channel layers and the plurality of capacitors, and electrically connected to the plurality of channel layers; and
a plurality of direct contacts (DC) spaced apart from the plurality of buried contacts (BC) with the plurality of channel layers disposed therebetween, and electrically connecting the plurality of channel layers to the plurality of bit lines,
wherein the plurality of word lines comprise: a plurality of selected word lines to which a positive voltage is applied; and a plurality of non-selected word lines to which a negative voltage is applied, and
the plurality of channel layers comprise: a selected channel layer that is turned on; and a non-selected channel layer that is turned off,
wherein one pair of word lines adjacent to ends of the selected channel layer in the second horizontal direction are all the selected word lines, and
at least one of one pair of word lines adjacent to ends of the non-selected channel layer in the second horizontal direction are each one of the non-selected word lines,
wherein the semiconductor memory device further comprises a plurality of sources and a plurality of drains located on the plurality of channel layers,
wherein a distance between each of at least two of the plurality of word lines and the bit lines in the vertical direction is a first distance or a second distance, and a word line of which a distance in the vertical direction is the first distance and a word line of which a distance in the vertical direction is the second distance are alternately arranged with each other to form a zigzag pattern,
wherein the first distance is shorter than the second distance.
